(19) United States
(12) Patent Application Publication
(10) Pub. No.: US 2009/0230544 A1
(43) Pub. Date: Sep. 17, 2009

(54) HEAT SINK STRUCTURE AND SEMICONDUCTOR PACKAGE AS WELL AS METHOD FOR CONFIGURING HEAT SINKS ON A SEMICONDUCTOR PACKAGE

(75) Inventors: Tong Hong WANG, Selangor D.E. (MY); Chang Chi LEE, Kaohsiung City (TW)

Correspondence Address: LOWE HAUPTMAN HAM & BERNER, LLP, 1700 DIAGONAL ROAD, SUITE 300, ALEXANDRIA, VA, 22314, US

(73) Assignee: ADVANCED SEMICONDUCTOR ENGINEERING INC., Pingtung City (TW)

(21) Appl. No.: 12/135,554

(22) Filed: Jun. 9, 2008

(30) Foreign Application Priority Data
Mar. 11, 2008 (TW) 097108438

(51) Int. Cl. H01L 23/367; H01L 21/56; F28F 7/00

(52) U.S. Cl. 257/712; 438/122; 165/185; 257/E23.101; 257/E21.502

(57) ABSTRACT

A heat sink structure according to the present invention is provided. The heat sink has a through opening extending from the upper surface through to the lower surface. A solder is disposed in the through opening and on the upper and lower surfaces of the heat sink, wherein the portion of the solder in the through opening is connected with the portions of the solder on the upper and lower surfaces.

### CROSS REFERENCE TO RELATED APPLICATION

This application claims the priority benefit of Taiwan Patent Application Serial Number 097108438 filed Mar. 11, 2008, the full disclosure of which is incorporated herein by reference.

### BACKGROUND OF THE INVENTION

1. Field of the Invention

The invention relates to a heat sink structure, a semiconductor package and a method for configuring heat sinks on a semiconductor package and more particularly, to a heat sink structure pre-applied with a layer of solder, a semiconductor package with the above heat sink structure and a method for configuring the above heat sink structure on a semiconductor package.

2. Description of the Related Art

High-performance flip chip ball grid array (HFCBGA) package is one of the reinforced packages that has a metal ring to support a heat sink for covering the package. Referring to FIG. 1, a conventional HBCBGA package 100 includes a substrate 102, a chip 104 disposed on the upper surface 108 of the substrate 102, a metal ring 106 disposed at the periphery of the upper surface 108 of the substrate 102 and surrounding the chip 104, and a heat sink 116 disposed on the chip 104 and the metal ring 106. In general, the chip 104 is electrically connected to the substrate 102 by a plurality of solder balls 110 and the solder balls 110 are covered with an underfill encapsulant 112. A plurality of solder balls 114 is disposed on the lower surface of the substrate 102 so that the package 100 can be electrically connected to external circuitry. In addition, to better dissipate the heat generated by the chip 104, another heat sink 126, such as a finned heat sink is disposed on the upper surface of the heat sink 116. Furthermore, a layer of thermal interface material (TIM) 132 is typically disposed between the chip 104 and the heat sink 116 to conduct heat from the chip 104 to the heat sink 116. Similarly, a layer of TIM 134 is disposed between the heat sinks 116 and 126 to conduct heat from the heat sink 116 to the heat sink 126.

However, the TIMs 132 and 134 are typically made of polymer material with a thermal conductivity of only about 4-5 W/mK. Therefore, when the package 100 consumes much power, said more than 100W, the conventional TIMs 132 and 134 cannot afford the requirement for heat dissipation.

Moreover, since the solder typically has a thermal conductivity of 30 W/mK, the solder made of pure indium, especially has a thermal conductivity of up to 80 W/mK, some manufactures have begun to offer such thermal interface material of solder. Referring to FIG. 2, there has been a type of heat sink in the market that a heat sink 204 coated with gold (Au) or nickel/gold (Ni/Au) 202 is applied a layer of solder 206.

Referring to FIGS. 3-5, the heat sink 204 of FIG. 2 can be attached to the chip 104 by the solder 206 with a reflow process (see FIG. 3). Afterward, the TIM 134 is applied to the opposing surface of the heat sink 204 (see FIG. 4). Finally, the finned heat sink 126 is disposed on the heat sink 204 and the TIM 134 is heated to bond the heat sinks 126 and 204 together. FIG. 5 illustrates the package with the heat sink 204 that is manufactured in accordance with the process described above.

However, it is likely that there will be a lot of voids formed in the solder 206 on the heat sink 204 after the reflow process. This phenomenon frequently occurs in the solder made of indium. The voids in the solder 206 will have an adverse effect on heat dissipation.

Accordingly, there exists a need to provide a heat sink structure to solve the above-mentioned problems.

### SUMMARY OF THE INVENTION

It is an object of the present invention to provide a heat sink structure that the heat sink has been applied with a solder.

In order to achieve the above object, the heat sink structure according to the present invention includes a first heat sink that has a through opening extending from the upper surface through to the lower surface. A solder made of such as indium is disposed in the through opening and on the upper and lower surfaces of the first heat sink, wherein the portion of the solder in the through opening is connected with the portions of the solder on the upper and lower surfaces.

It is another object of the present invention to provide a method for configuring heat sinks on a semiconductor package.

In order to achieve the above object, the method for configuring heat sinks on a semiconductor package according to the present invention is first to provide a substrate. A chip is disposed on the upper surface of the substrate. The active surface of the chip is faced down and electrically connected to the substrate by a plurality of first solder balls. The first solder balls are covered with an underfill encapsulant. A plurality of second solder balls is disposed on the lower surface of the substrate to enable the chip to be electrically connected to external circuitry. Furthermore, a metal ring is disposed on the upper surface of the substrate and surrounds the chip. Afterward, the heat sink structure with the solder on the first heat sink according to the present invention is disposed on the chip. A second heat sink is then disposed on the upper surface of the first heat sink. Finally, a reflow process is performed to have the portions of the solder on the upper and lower surfaces of the first heat sink firmly affixed to the second heat sink and the chip, respectively.

According to the method of the present invention for configuring heat sinks on a semiconductor package, the solder pre-applied on the heat sink acts as a thermal interface material. The heat sink with the solder can be attached to a chip and another heat sink by only a reflow process. The time for configuring the heat sinks on the package can be greatly reduced accordingly. Moreover, when there are voids formed in the portions of the solder between the heat sink and chip or between the heat sinks after the reflow process, the resulting package can be reflowed again to have the solder melted. The portion of the melted solder in the through opening will flow out to fill the voids. Therefore, the rework can be easily carried out without the need of detaching the heat sinks.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 illustrates a conventional reinforced package with a heat sink.

FIG. 2 illustrates a conventional heat sink pre-applied with a layer of solder.

FIGS. 3 to 5 illustrate a method for configuring heat sinks on a semiconductor package in the art.

FIG. 6a illustrates the heat sink structure of the present invention, wherein a solder is disposed in the through opening and on the lower surface of the heat sink.

FIG. 6b illustrates the heat sink structure of the present invention, wherein a solder is disposed in the through opening and on the upper and lower surfaces of the heat sink.

FIG. 6c illustrates the heat sink structure of the present invention, wherein a solder is disposed in the through opening and on all of the upper surface and part of the lower surface of the heat sink.

FIGS. 7a to 7b illustrate the method for configuring heat sinks on a semiconductor package according to the present invention.

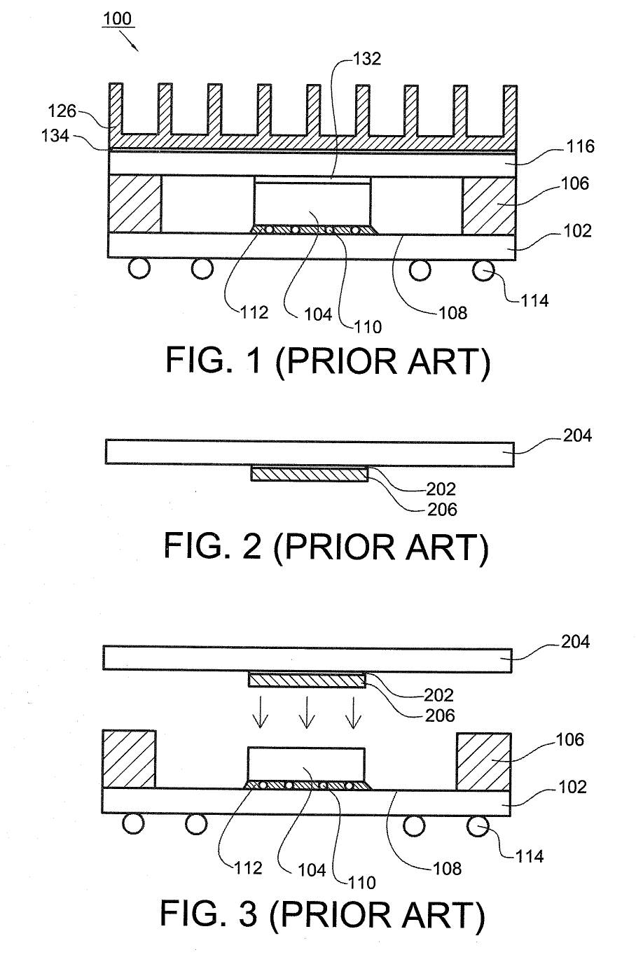

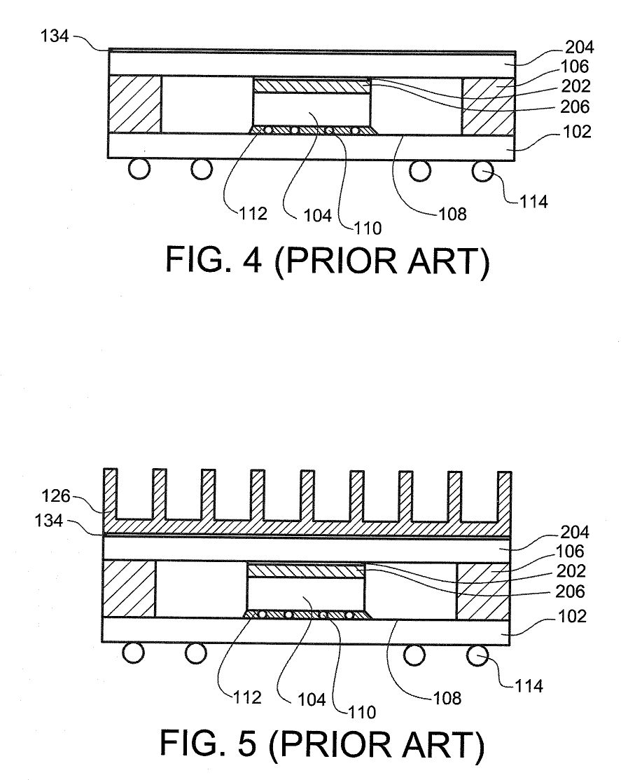

### DETAILED DESCRIPTION OF THE PREFERRED EMBODIMENTS

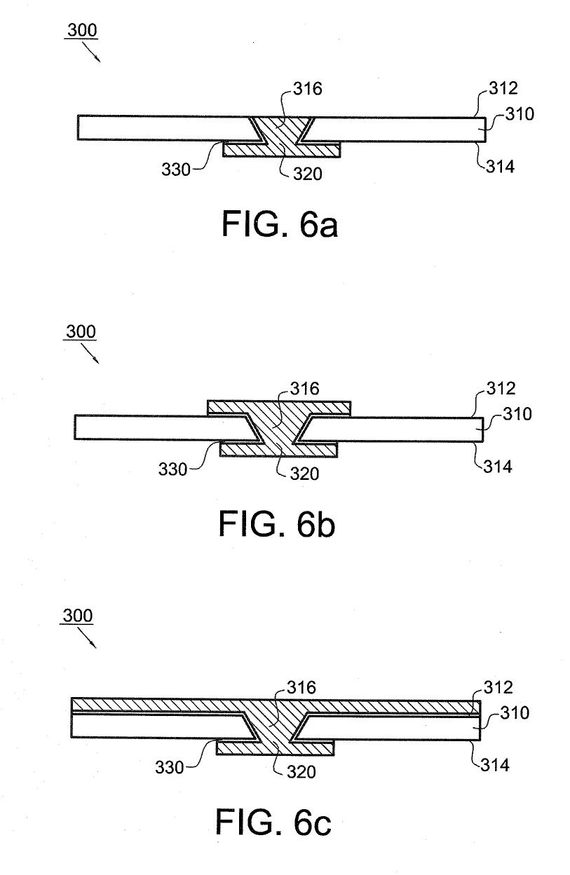

Referring to FIGS. 6a and 6c, the heat sink structure 300 according to the present invention includes a heat sink 310 that has a through opening 316 extending from the upper surface 312 through to the lower surface 314. A solder 320 as a metal interface material, made of such as indium, silver, lead or alloys thereof is disposed in the through opening 316 and on the lower surface 314 of the heat sink 310. Moreover, the solder 320 can be further disposed on full or part of the upper surface 312, wherein the portion of the solder 320 in the through opening 316 is connected with the portions of the solder on the upper and lower surfaces 312, 314. The inner wall of the through opening 316 and the portions of the upper and lower surfaces 312, 314 in contact with the solder 320 can be optionally coated with a layer of Au or Ni/Au material 330.

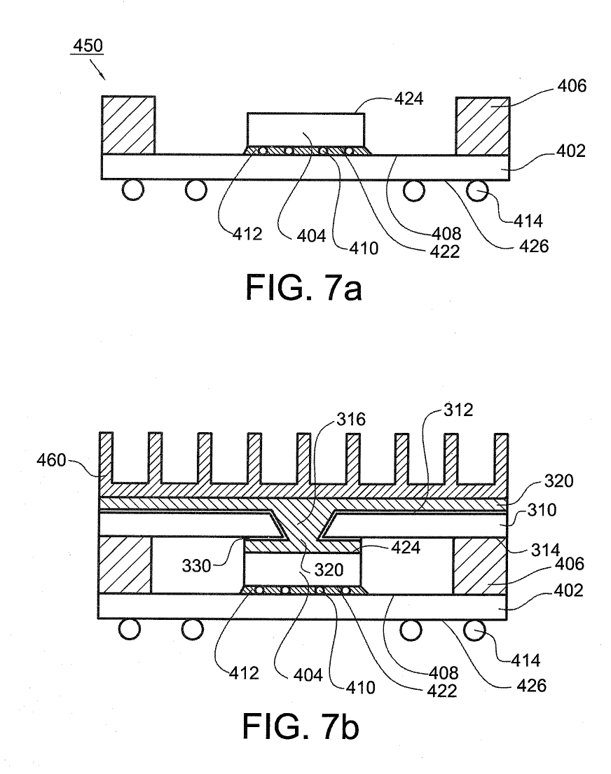

Referring to FIGS. 7a and 7b, they illustrate the method for configuring heat sinks on a semiconductor package according to the present invention. First, a semiconductor package 450 is provided. The semiconductor package 450 includes a substrate 402 and a chip 404 disposed on the upper surface 408 of the substrate 402. The active surface 422 of the chip 404 is faced down and electrically connected to the substrate 402 by a plurality of solder balls 410. The solder balls 410 are covered with an underfill encapsulant 412. A plurality of solder balls 414 is disposed on the lower surface 426 of the substrate 402 to enable the chip 404 to be electrically connected to external circuitry. Furthermore, a metal ring 406 is disposed on the upper surface 408 of the substrate 402 and surrounds the chip 404. FIG. 7 illustrates the semiconductor package 450.

Afterward, referring to FIG. 7b, the heat sink structure 300 of FIG. 6c is disposed on the chip 404 and the ring 406, and the portion of the solder 320 on the lower surface 314 of the heat sink 310 is brought into contact with the backside 424 of the chip 404. Moreover, another heat sink 460, such as a fin-like heat sink is disposed on the upper surface 312 of the heat sink 310 and brought into contact with the portion of the solder 320 on the upper surface 312 of the heat sink 310. Finally, a reflow process is performed on the heat sink structure 300 to position the solder 320 on the upper and lower surfaces 312, 314 of the heat sink 310 firmly affixed to the heat sink 460 and the chip 404, respectively. In this manner the heat sink 310 is in good thermal contact with the heat sink 460 and chip 404 by the solder 320 and the heat generated by the chip 404 can be dissipated with the heat sinks 310, 460 accordingly.

According to the method of the present invention for configuring heat sinks on a semiconductor package, the solder pre-applied on the heat sink acts as a thermal interface material. The heat sink with the solder can be attached to a chip and another heat sink by reflow process only once. The time for fixing the heat sinks on the package can be greatly reduced accordingly. Moreover, when there are voids formed in the portions of the solder between the heat sink and chip or between the heat sinks after the reflow process, the resulting package can be reflowed again to have the solder melted. The portion of the melted solder in the through opening will flow out to fill the voids. Therefore, the rework can be easily carried out without the need of detaching the heat sinks.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A heat sink structure, comprising:
a heat sink having a first surface, a second surface opposing to the first surface and a through opening extending from the first surface through to the second surface; and
a solder disposed in the through opening and on the second surface of the heat sink, wherein the portion of the solder in the through opening is connected with the portion of the solder on the second surface.

2. The heat sink structure as claimed in claim 1, wherein the solder is further disposed on the first surface of the heat sink and the portion of the solder in the through opening is connected with the portion of the solder on the first surface.

3. The heat sink structure as claimed in claim 2, wherein the solder is disposed on substantially full of the first surface of the heat sink.

4. The heat sink structure as claimed in claim 2, further comprising:
a gold layer coated on the heat sink and in contact with the solder.

5. The heat sink structure as claimed in claim 2, further comprising:
a nickel/gold layer coated on the heat sink and in contact with the solder.

6. The heat sink structure as claimed in claim 2, wherein the solder is made of indium or alloys thereof.

7. A method for configuring heat sinks on a semiconductor package, comprising the steps of:
providing a substrate, the substrate having upper and lower surfaces;
disposing a chip on the upper surface of the substrate;
providing a first heat sink, the first heat sink having upper and lower surfaces, wherein the upper and lower surfaces of the first heat sink are pre-applied with a solder;
disposing the first heat sink on the chip;
disposing a second heat sink on the first heat sink; and
performing a reflow process to have the portions of the solder on the upper and lower surfaces of the first heat sink affixed to the second heat sink and the chip, respectively.

8. The method as claimed in claim 7, further comprising:
disposing a ring between the upper surface of the substrate and the lower surface of the first heat sink, the ring surrounding the chip.

9. The method as claimed in claim 7, wherein the first heat sink further comprises a through opening extending from the upper surface through to the lower surface, the solder is further disposed in the through opening and the portion of the solder in the through opening is connected with the portions of the solder on the upper and lower surfaces of the first heat sink.

10. The method as claimed in claim 7, wherein the solder is made of indium or alloys thereof.

11. The method as claimed in claim 7, wherein the chip has an active surface, the active surface of the chip is faced down on the upper surface of the substrate, the method further comprises:
disposing a plurality of first solder balls on the active surface of the chip and electrically connecting the first solder balls to the upper surface of the substrate; and
covering the first solder balls with an underfill encapsulant.

12. The method as claimed in claim 11, further comprising:
disposing a plurality of second solder balls on the lower surface of the substrate.

13. A semiconductor package, comprising:
a substrate having upper and lower surfaces;
a chip disposed on the upper surface of the substrate;
a first heat sink disposed on the chip, having an upper surface, a lower surface and a through opening extending from the upper surface through to the lower surface; and
a solder affixed in the through opening of the first heat sink and between the chip and first heat sink.

14. The semiconductor package as claimed in claim 13, further comprising:
a second heat sink disposed on the first heat sink,
wherein the solder is further affixed between the first and second heat sinks and is connected with the portion of the solder in the through opening.

15. The semiconductor package as claimed in claim 13, further comprising:
a ring disposed between the upper surface of the substrate and the lower surface of the first heat sink, the ring surrounding the chip.

16. The semiconductor package as claimed in claim 13, wherein the solder is made of indium or alloys thereof.

17. The semiconductor package as claimed in claim 13, wherein the chip has an active surface, the active surface of the chip is faced down on the upper surface of the substrate, the semiconductor package further comprises:
a plurality of first solder balls disposed on the active surface of the chip and electrically connected to the upper surface of the substrate; and
an underfill encapsulant covering the first solder balls.

18. The semiconductor package as claimed in claim 13, further comprising:
a plurality of second solder balls disposed on the lower surface of the substrate.
